(19) United States
(12) Patent Application Publication
(10) Pub. No.: US 2017/0011905 A1
(43) Pub. Date: Jan. 12, 2017

(54) METHOD OF MAKING A PACKAGED SEMICONDUCTOR DEVICE

(71) Applicant: FREESCALE SEMICONDUCTOR, INC., Austin, TX (US)

(72) Inventor: RAMA I. HEGDE, Austin, TX (US)

(21) Appl. No.: 14/793,882

(22) Filed: Jul. 8, 2015

(51) Int. Cl. H01L 21/02; B08B 3/08

(52) U.S. Cl. CPC H01L 21/02068; B08B 3/08

(57) ABSTRACT

A method of removing metal oxide from electrically conductive contacts of a packaged semiconductor device includes mixing a solution including vinegar and nitric acid, applying the solution to the contacts for a time sufficient to remove the metal oxide from the contacts, and rinsing the solution from the contacts.

### BACKGROUND

Field

This disclosure relates generally to semiconductor devices, and more particularly, to packaged semiconductor devices.

Related Art

Semiconductor devices are packaged for a variety of reasons such as being convenient for mounting to a surface such as a circuit board or an interior surface of a product. Other reasons are for protection from contamination during its life in a product, during the manufacturing of the product that contains the semiconductor device, and during storage prior to shipping to the manufacturer of the product. The manufacturer of the product, in mounting the semiconductor device as part of the product, needs to be able to reliably perform that mounting both from a structural integrity and electrical integrity standpoint. The packaged semiconductor device desirably has its bonding surfaces ready for the mounting in a manner that results in a reliable bond for both structural and electrical integrity.

Accordingly there is a need to provide further improvement in obtaining packaged semiconductor devices that have mounting surfaces onto which reliable structural and electrical bond can be made.

### BRIEF DESCRIPTION OF THE DRAWINGS

The present invention is illustrated by way of example and is not limited by the accompanying figures, in which like references indicate similar elements. Elements in the figures are illustrated for simplicity and clarity and have not necessarily been drawn to scale.

Shown in FIG. 1 is a cross section of a packaged semiconductor device at a stage in a processing;

Shown in FIG. 2 is a cross section of the packaged semiconductor device of FIG. 1 at a subsequent stage in processing;

Shown in FIG. 3 is a cross section of the packaged semiconductor device of FIG. 2 at a subsequent time;

Shown in FIG. 4 is a cross section of the packaged semiconductor device of FIG. 3 at a subsequent stage in processing;

Shown in FIG. 5 is the packaged semiconductor device being subjected to a cleaning solution at a stage in processing between the stages shown in FIGS. 3 and 4; and

FIG. 6 is a lead frame that may be subjected to the cleaning solution of FIG. 5.

### DETAILED DESCRIPTION

In one aspect, a packaged semiconductor device with leads that contain copper but in which the copper is not intended to be on the bonding surface of the leads has the leads cleaned prior to mounting in a product with a solution of vinegar and nitric acid. This is better understood by reference to the drawings and the following written description.

Shown in FIG. 1 is a packaged semiconductor device 10 having a packaged integrated circuit 12 and a lead 14 extending from packaged integrated circuit 12. Lead 14 has an inner conductor 16 that may comprise copper or aluminum, a nickel layer 22 on a top surface of inner conductor 16 and a nickel layer 28 on a bottom surface of inner conductor 16, a palladium layer 20 on nickel layer 22 and a palladium layer 26 on nickel layer 28, and a gold layer 18 on palladium layer 20 and a gold layer 24 on palladium layer 26. Nickel layers 22 and 28 extend around inner conductor 16 as a single continuous layer. Palladium layers 20 and 26 extend around nickel layers 22 and 28 as a single continuous layer. Gold layers 18 and 24 extend around palladium layers 20 and 26 to form a single continuous layer. Gold layers 18 and 24 may have a thickness in the range of 5 to 500 Angstroms. Palladium layers 20 and 26 may have a thickness in the range of 20 to 500 Angstroms. Nickel layers 22 and 28 may have a thickness in the range of 0.2 to 2 microns. Inner conductor 16 may be in the range of 20 to 2000 microns.

Shown in FIG. 2 is packaged semiconductor device 10 after cutting lead 14 to leave an edge 30 that exposes an end portion of inner conductor 16 as well as end portions of nickel layers 22 and 28, palladium layers 20 and 26, and gold layers 18 and 24. Edge 30 is thus exposed and not constrained by nickel layers 22 and 28, palladium layers 20 and 26, and gold layers 18 and 24. Thus atoms from inner conductor 16 can migrate.

Shown in FIG. 3 is packaged semiconductor device 10 after migration of atoms from inner conductor 16 that have formed an upper oxide layer 32 on a top surface of gold layer 18 and a lower oxide layer 34 on bottom surface of gold layer 24. Copper and aluminum, especially copper, migrate when there is an available path. As migration occurs, exposed to ambient, oxidation also occurs forming oxide layer 32 on the upper surface of gold layer 18 and oxide layer 34 on the bottom surface of gold layer 24. Oxide layers 32 and 34 may extend around lead 14 and thus may join together to form a continuous layer. Both aluminum and copper oxides have a substantially non-conductive characteristic. Attempts to bond to lead 14 through oxide layers 32 and 34 are unreliable. At this stage, oxide is formed but there may still some metallic residue of copper or aluminum that has not yet reacted with oxygen.

Shown in FIG. 4 is packaged semiconductor device 10 after removing oxide layers 32 and 34 and metallic residue by inserting packaged semiconductor device 10 into a bath 36 of a mixture of vinegar and nitric acid 38 shown in FIG. 5. This mixture may be referenced as a solution. The immersion may be, for example, 5 seconds to 5 minutes. The nitric acid may be a relatively low percentage of the mixture which makes the mixture comparatively benign to packaged semiconductor device 10. The vinegar is very effective in disassociating the oxygen from oxide layers 32 and 34 and the nitric acid is very effective at reacting with the copper or aluminum. The vinegar, which is commercially available, may be distilled white vinegar with 5% acidity achieved with acetic acid. Other vinegars may also be found to be effective. The nitric acid may be a very low percentage, for example, achieved with one or two drops of 69.5 per cent nitric acid per liter of the vinegar. More drops may be beneficial without harming the packaged semiconductor device. The concentration amount of vinegar, after adding the nitric acid of 69.5 percent nitric acid, may be, for example, 99.995% and the nitric acid still be effective for its intended purpose of removing residual copper. A variety of factors, such as to what thickness and extent the undesired oxide has achieved, affect the time. After the treatment with the solution of vinegar and nitric acid, a rinse is performed to remove the solution and the residue from the reactions. The rinse may be performed using one or more of acetone and isopropyl alcohol. The rinse may be performed at room temperature and may be applied for a time ranging from 5 to 300 seconds. After rinsing, a drying of the contacts is performed in an ambient that includes nitrogen.

It is believed that the oxygen is removed from copper oxide, for example, by the following reaction: CuO+2CH₃COOH (vinegar)->Cu(CH₃COO)₂+H₂O. With this reaction, the result is water and Cu(CH₃COO)₂ which dissolves in water. Vinegar will also result in a similar reaction with aluminum oxide. The oxide may include other elements in addition to the metal and oxygen such as carbon and hydrogen. Examples include Cu(OH)₂, CuCO₃, and Cu₂CO₃(OH)₂ as well as others. In such cases, the copper becomes associated with elements that cause the combination to be water soluble. As for the metallic residue that has not yet reacted with oxygen, it is desirable that it be removed because it will almost certainly eventually react with oxygen and form the non-conducting oxide. The metallic residue is reacted with nitric acid to leave material easily removed with water. The reaction for the case of copper may be: Cu+4HNO₃ (nitric acid)->Cu(NO₃)₂+2NO₂+2H₂O.

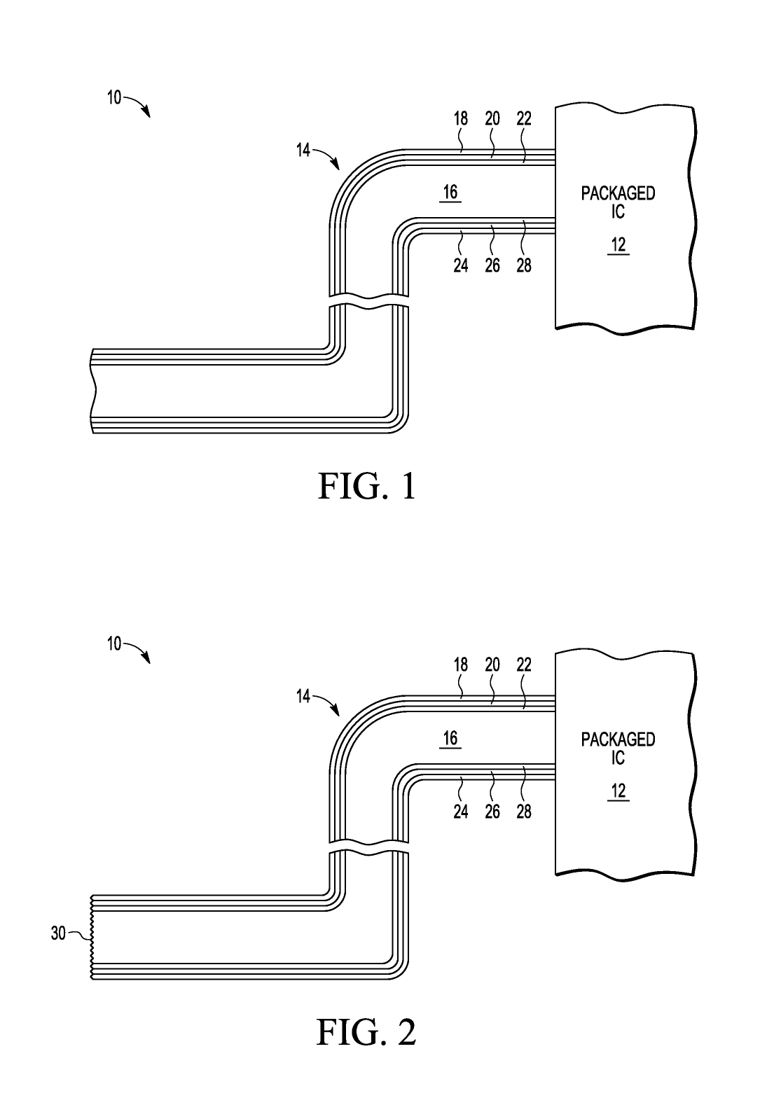

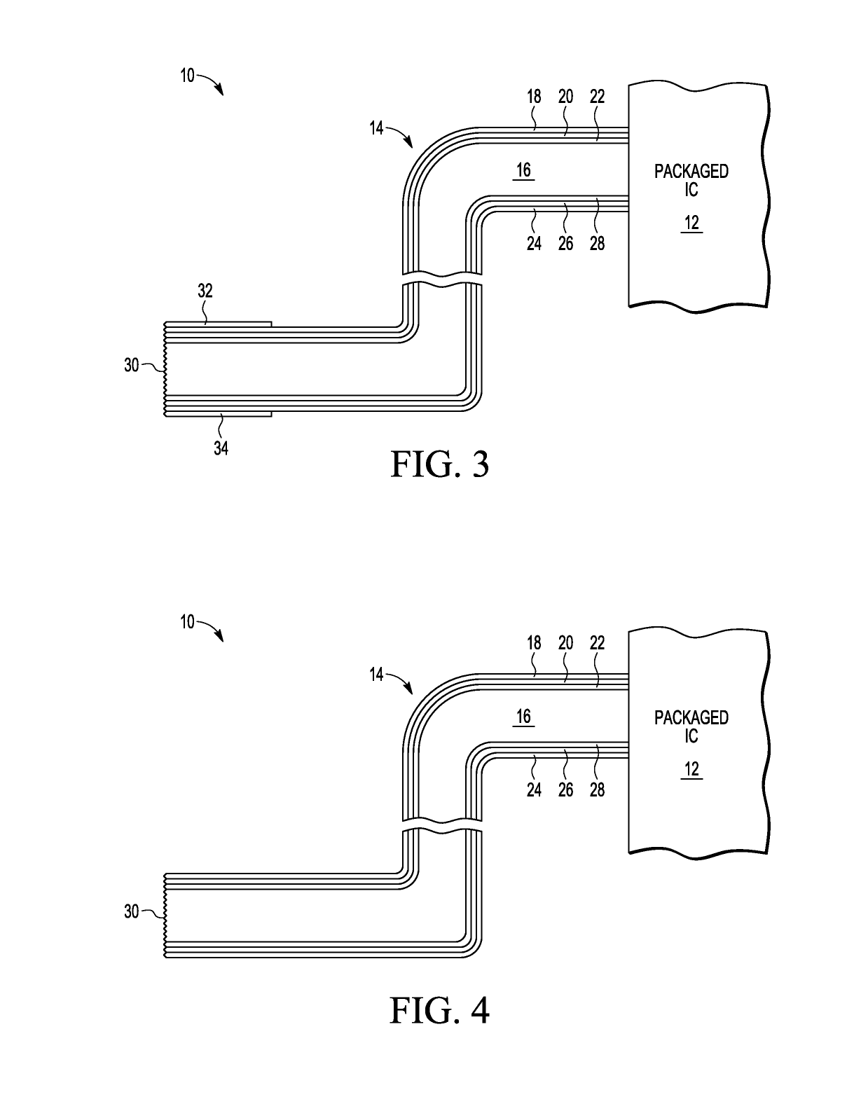

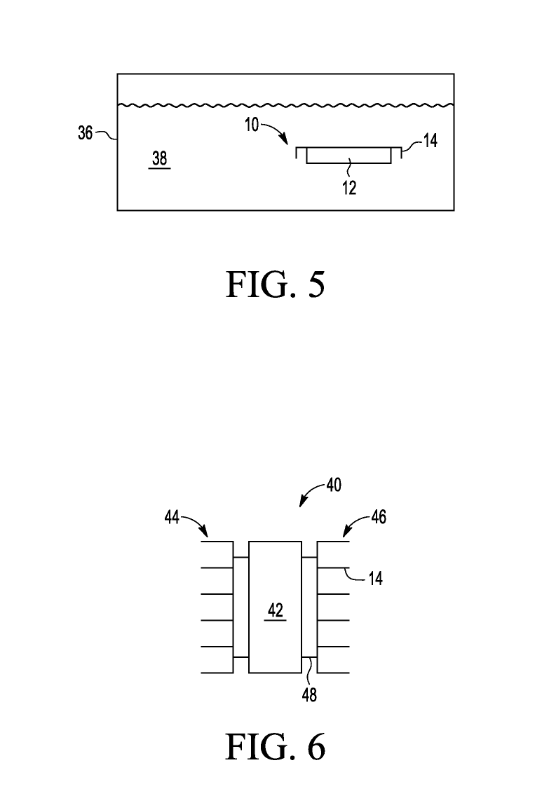

Shown in FIG. 6 is a lead frame 40 having a flag 42 for having an integrated circuit mounted thereon, a plurality of leads 44 on one side, a plurality of leads 46 on the other side of which lead 14 of FIG. 1 is one, and a connection 48 maintaining structural unity between flag 42 and leads 46 during the process of mounting the integrated circuit to lead frame 40. Prior to lead frame 40 having the integrated circuit mounted thereto, lead frame 40 may be treated with the vinegar and nitric acid to remove oxide. This treatment may be achieved by inserting lead frame 40 into bath 36 having nitric acid 38. This may be particularly beneficial in the case where the lead frame's outer layer is a metal, such as tin, that can be oxidized.

Thus, it is seen that oxides formed from aluminum or copper arising from migration or otherwise of the exposure of the end of the lead being cut can be removed, using vinegar and nitric acid, so as to enable formation of a reliable connection to the lead. This same approach can be used on a lead frame itself.

By now it should be appreciated that there has been provided a method of removing metal oxide from electrically conductive contacts of a packaged semiconductor device. The method includes mixing a solution including vinegar and nitric acid. The method further includes applying the solution to the electrically conductive contacts for a time sufficient to remove the metal oxide from the electrically conductive contacts. The method further includes rinsing the solution from the electrically conductive contacts. The method may have a further characterization by which the vinegar includes two to ten percent acetic acid. The method may have a further characterization by which the vinegar is 99.9 to 99.95 percent of the solution by volume. The method may have a further characterization by which the nitric acid is 0.05 to 0.1 percent of the solution by volume. The method may have a further characterization by which the metal oxide is copper oxide. The method may have a further characterization by which the metal oxide comprises one of a group consisting of: tin oxide and aluminum oxide. The method may have a further characterization by which the electrically conductive contacts comprise one of a group consisting of: contacts on a substrate, contacts on a quad flat no-lead package, and leads on a quad flat lead package. The method may have a further characterization by which the rinsing is performed with distilled water followed by one of a group consisting of acetone and isopropyl alcohol. The method may have a further characterization by which the solution is applied to the electrically conductive contacts at room temperature. The method may have a further characterization by which the solution is applied to the electrically conductive contacts for a time ranging from five to three hundred seconds. The method may have a further characterization by which drying the electrically conductive contacts in an ambient that includes nitrogen. The method may have a further characterization by which the electrically conductive contacts include a layer of metal from which the metal oxide is formed, a layer of nickel over the layer of metal, a layer of palladium over the layer of nickel, and a layer of gold over the layer of palladium. The method may further include applying the solution to only a portion of the electrically conductive contacts.

Also disclosed is a method of removing metal oxide from a semiconductor device carrier. The method includes mixing a solution that includes vinegar. The method further includes applying the solution to at least a portion of the semiconductor device carrier. The method further includes allowing the solution to remain on the device carrier for a time sufficient to remove a desired amount of the metal oxide from the semiconductor device carrier. The method may have a further characterization by which rinsing the solution from the semiconductor device carrier using distilled water. The method may have a further characterization by which drying the semiconductor device carrier in an inert gas ambient. The method may further allowing the solution to remain on the device carrier for a time sufficient to remove metal from which the metal oxide was formed, from at least a portion of an exposed outer layer of the device carrier. The method may have a further characterization by which the vinegar includes two to ten percent acetic acid. The method may have a further characterization by which the vinegar is 99.9 to 99.95 of the solution by volume and the solution further includes nitric acid that is 0.05 to 0.1 percent of the solution by volume and the solution is applied to the electrically conductive contacts for a time ranging from five to three hundred seconds. The method may have a further characterization by which the metal oxide comprises one of a group consisting of: tin oxide, aluminum oxide, and copper oxide. The method may have a further characterization by which at least a portion of the semiconductor device carrier includes a layer of metal from which the metal oxide is formed, a layer of nickel over the layer of metal, a layer of palladium over the layer of nickel, a layer of gold over the layer of palladium, and a layer of the metal oxide over the layer of gold before the metal oxide is removed.

Although the invention is described herein with reference to specific embodiments, various modifications and changes can be made without departing from the scope of the present invention as set forth in the claims below. For example, the particular amount of time for different operations may be able to be varied further as may also the particular materials of the conductive layers. Also the mixture of vinegar and nitric acid may be applied in manner other than submersion in a bath such as application by spray, application by the mixture moving, and application to only a portion of the lead frame or packaged semiconductor device contact the mixture. Accordingly, the specification and figures are to be regarded in an illustrative rather than a restrictive sense, and all such modifications are intended to be included within the scope of the present invention. Any benefits, advantages, or solutions to problems that are described herein with regard to specific embodiments are not intended to be construed as a critical, required, or essential feature or element of any or all the claims.

The term “coupled,” as used herein, is not intended to be limited to a direct coupling or a mechanical coupling.

Furthermore, the terms “a” or “an,” as used herein, are defined as one or more than one. Also, the use of introductory phrases such as “at least one” and “one or more” in the claims should not be construed to imply that the introduction of another claim element by the indefinite articles “a” or “an” limits any particular claim containing such introduced claim element to inventions containing only one such element, even when the same claim includes the introductory phrases “one or more” or “at least one” and indefinite articles such as “a” or “an.” The same holds true for the use of definite articles.

Unless stated otherwise, terms such as “first” and “second” are used to arbitrarily distinguish between the elements such terms describe. Thus, these terms are not necessarily intended to indicate temporal or other prioritization of such elements.

What is claimed is:

1. A method of removing metal oxide from electrically conductive contacts of a packaged semiconductor device comprising:
mixing a solution including vinegar and nitric acid;
applying the solution to the electrically conductive contacts for a time sufficient to remove the metal oxide from the electrically conductive contacts; and
rinsing the solution from the electrically conductive contacts.

2. The method of claim 1 wherein:
the vinegar includes two to ten percent acetic acid.

3. The method of claim 1 wherein:
the vinegar is 99.9 to 99.95 percent of the solution by volume.

4. The method of claim 3 wherein:
the nitric acid is 0.05 to 0.1 percent of the solution by volume.

5. The method of claim 1 wherein:
the metal oxide is copper oxide.

6. The method of claim 1 wherein:
the metal oxide comprises one of a group consisting of: tin oxide and aluminum oxide.

7. The method of claim 1 wherein:
the electrically conductive contacts comprise one of a group consisting of: contacts on a substrate, contacts on a quad flat no-lead package, and leads on a quad flat lead package.

8. The method of claim 1 wherein:
the rinsing is performed with distilled water followed by one of a group consisting of acetone and isopropyl alcohol.

9. The method of claim 1 wherein:
the solution is applied to the electrically conductive contacts at room temperature.

10. The method of claim 1 wherein:
the solution is applied to the electrically conductive contacts for a time ranging from five to three hundred seconds.

11. The method of claim 1 further comprising:
drying the electrically conductive contacts in an ambient that includes nitrogen.

12. The method of claim 1 wherein the electrically conductive contacts include:
a layer of metal from which the metal oxide is formed;
a layer of nickel over the layer of metal;
a layer of palladium over the layer of nickel; and
a layer of gold over the layer of palladium.

13. The method of claim 1 further comprising:
applying the solution to only a portion of the electrically conductive contacts.

14. A method of removing metal oxide from a semiconductor device carrier comprising:
mixing a solution that includes vinegar;
applying the solution to at least a portion of the semiconductor device carrier; and
allowing the solution to remain on the device carrier for a time sufficient to remove a desired amount of the metal oxide from the semiconductor device carrier.

15. The method of claim 14 further comprising:
rinsing the solution from the semiconductor device carrier using distilled water; and
drying the semiconductor device carrier in an inert gas ambient.

16. The method of claim 14 further comprising:
allowing the solution to remain on the device carrier for a time sufficient to remove metal from which the metal oxide was formed, from at least a portion of an exposed outer layer of the device carrier.

17. The method of claim 14 wherein:
the vinegar includes two to ten percent acetic acid.

18. The method of claim 14 wherein:
the vinegar is 99.9 to 99.95 of the solution by volume and the solution further includes nitric acid that is 0.05 to 0.1 percent of the solution by volume; and
the solution is applied to the electrically conductive contacts for a time ranging from five to three hundred seconds.

19. The method of claim 14 wherein:
the metal oxide comprises one of a group consisting of: tin oxide, aluminum oxide, and copper oxide.

20. The method of claim 14 wherein at least a portion of the semiconductor device carrier includes:
a layer of metal from which the metal oxide is formed;
a layer of nickel over the layer of metal;
a layer of palladium over the layer of nickel;
a layer of gold over the layer of palladium; and
a layer of the metal oxide over the layer of gold before the metal oxide is removed.
